(19) United States
(12) Patent Application Publication
(10) Pub. No.: US 2022/0166413 A1
(43) Pub. Date: May 26, 2022

(54) COMPARATOR SET-RESET LATCH CIRCUIT AND METHOD FOR CAPACITIVELY STORING BITS

(71) Applicant: Rambus Inc., San Jose, CA (US)

(72) Inventors: Clifford TING, Toronto (CA); Hemesh YASOTHARAN, Toronto (CA); Navid YAGHINI, Pickering (CA); Robert WANG, Toronto (CA); Zhuobin LI, Markham (CA)

(21) Appl. No.: 17/535,776

(22) Filed: Nov. 26, 2021

Related U.S. Application Data
(60) Provisional application No. 63/118,717, filed on Nov. 26, 2020.

(51) Int. Cl. H03K 3/037; H03K 5/24

(52) U.S. Cl. CPC H03K 3/037; H03K 5/24

(57) ABSTRACT

A circuit and method for storing bit values in capacitors of a set-reset latch of a dynamic comparator are described. A capacitor-based SR latch architecture is disclosed that makes use of the parasitic capacitances present at its output to store a digital bit value. During the comparator's sampling phase, the capacitor-based SR latch behaves as an inverter and buffers the sampled value to the output of the SR latch. In doing so, it charges the parasitic capacitors associated with the routing and downstream circuitry up or down. When the dynamic comparator enters the reset phase, the SR latch turns off and makes use of the of the parasitic capacitors to hold the previously-buffered value.

### CROSS-REFERENCE TO RELATED APPLICATION

This application claims the benefits of priority to U.S. Provisional Patent Application No. 63/118,717, filed Nov. 26, 2020, titled COMPARATOR SET-RESET LATCH CIRCUIT AND METHOD FOR CAPACITIVELY STORING BITS, the contents of which are hereby expressly incorporated into the present application by reference in their entirety.

### FIELD

The present disclosure relates to dynamic comparators. In particular, it relates to circuits and methods for storing bit values in capacitors of a set-reset latch of a dynamic comparator.

### BACKGROUND

A comparator is a device used in electronic circuits that compares two voltages or currents and generates a digital signal indicating which of the currents or voltages is greater. A typical comparator has two analog input terminals, which may be denoted In+ and In−, and a binary digital output terminal Out. The signal generated by the comparator at the output terminal Out typically corresponds to a high Boolean value (e.g., 1) if In+>In−, and a low Boolean value (e.g., 0) if In+<In−.

Some comparators are clocked. Clocked comparators, also called dynamic comparators, receive a third input signal, a clock signal. The value of Out is only updated at clock signal edges (i.e. clock transitions). In a dynamic comparator, the values of In+ and In− are only relevant for a short period of time around the clock transition. The speed of dynamic comparators may be very high while resulting in very low power dissipation. Dynamic comparators are often used in the design of high-speed analog-to-digital converters (ADCs).

A dynamic comparator may consist of a dynamic latch followed by a set-reset (SR) latch. The SR latch buffers and stores the digital bit sampled from the dynamic latch so that it can be passed to a set of registers and/or other digital logic connected to the comparator's output Out.

FIG. 1 (prior art) shows an example of a conventional SR latch 10 of a dynamic comparator. The conventional SR latch 10 receives inputs Mid+ 12 and Mid− 14 from the dynamic latch and generates outputs Out+ 16 and Out− 18. A voltage power supply VoD 20 supplies power to the source terminal of four PMOS transistors: first transistor 22, second transistor 24, third transistor 26, and fourth transistor 28. Mid+ 12 is connected to the gate terminal of the first transistor 22, and Mid− 14 is connected to the gate terminal of the fourth transistor 28. The drain terminals of the first transistor 22 and second transistor 24 are connected to Out+ 16, and the drain terminals of the third transistor 26 and fourth transistor 28 are connected to Out− 18. Out+ 16 is also connected to the gate terminal of the third transistor 26, and Out− 18 is also connected to the gate terminal of the second transistor 24.

Four NMOS (N-type metal-oxide-semiconductor logic) transistors are arranged below the four PMOS (P-type metal-oxide-semiconductor logic) transistors: fifth transistor 30, sixth transistor 32, seventh transistor 34, and eighth transistor 36. Out− 18 is connected to the gate terminal of the fifth transistor 30 and to the drain terminal of the sixth transistor 32. Out+ 16 is connected to the gate terminal of the sixth transistor 32 and to the drain terminal of the fifth transistor 30. Mid+ 12 is connected to the gate terminal of the seventh transistor 34, and Mid− 14 is connected to the gate terminal of the eighth transistor 36. The source terminal of the fifth transistor 30 is connected to the drain terminal of the seventh transistor 34, and the source terminal of the sixth transistor 32 is connected to the drain terminal of the eighth transistor 36. The source terminals of the seventh transistor 34 and eighth transistor 36 are connected to voltage terminal Vₛₛ 38, which effectively acts as ground for the conventional SR latch 10.

Thus, the conventional SR latch 10 architecture for a dynamic comparator shown in FIG. 1 requires multiple cross-coupled transistors 22 through 36 to hold the output voltage during the reset phase, consuming a relatively large amount of power from the power supply (e.g., V_{DD} 20) and potentially introducing delay between the clock edge and the outputs (e.g., outputs 16 and 18). In addition, this architecture may require relatively large transistors, potentially reducing the sensitivity of the comparator.

There thus exists a need for a dynamic comparator or SR latch that overcomes one or more of the disadvantages of existing architectures identified above.

### SUMMARY

The present disclosure describes example circuits and methods for storing bit values in capacitors of a set-reset latch of a dynamic comparator. A capacitor-based SR latch architecture is disclosed that makes use of the parasitic capacitances present at its output to store a digital bit value. During the comparator's sampling phase, the capacitor-based SR latch behaves as an inverter and buffers the sampled value to the output of the SR latch. In doing so, it charges the parasitic capacitors associated with the routing and downstream circuitry up or down. When the dynamic comparator enters the reset phase, the SR latch turns off and makes use of the of the parasitic capacitors to hold the previously-buffered value.

The use of parasitic capacitors to store the output value instead of cross-couple transistors may result in one or more advantages over existing SR latch architectures. Using the capacitors to store bit values may reduce the comparator's power consumption and may reduce the delay between clock edges and comparator output. In addition, use of capacitors to store bit values may allow the SR latch to be designed using transistors that are reduced in size relative to those of conventional SR latches, thereby potentially improving the overall sensitivity of the comparator.

According to some aspects, the present disclosure describes a set-reset latch circuit. The set-reset latch circuit comprises at least one output terminal, and a plurality of transistors collectively configured to receive a first input signal Mid+ and a second input signal Mid−, provide a first output signal level to the at least one output terminal when the first input signal Mid+ is at a first input signal level and the second input signal Mid− is at a second input signal level, and provide a second output signal level to the at least one output terminal when the first input signal Mid+ is at the second input signal level and the second input signal Mid− is at the first input signal level. The at least one output terminal maintains its signal level using parasitic capacitance when the first input signal Mid+ is at the second input signal level and the second input signal Mid− is at the second input signal level.

According to a further aspect which can be combined with other embodiments disclosed herein, the at least one output terminal comprises: a first output terminal providing a first output signal Out+, and a second output terminal providing a second output signal Out− having an output signal level that is the inverse of the output signal level of the first output signal.

According to a further aspect which can be combined with other embodiments disclosed herein, the plurality of transistors comprises a first transistor gated by an inverted version of the first input signal Mid+ and providing its output to the first output terminal, a second transistor gated by an inverted version of the second input signal Mid− and providing its output to the second output terminal, a third transistor gated by the second input signal Mid− and receiving the first output signal at its drain terminal, and a fourth transistor gated by the first input signal Mid+ and receiving the second output signal at its drain terminal.

According to some aspects, the present disclosure describes a dynamic comparator circuit. The dynamic comparator circuit comprises the set-reset latch circuit described above, and a dynamic latch. The dynamic latch is configured to receive two comparator input signals, generate the first input signal Mid+ and second input signal Mid− in response thereto, and provide the first input signal Mid+ and second input signal Mid− to the set-reset circuit.

According to a further aspect which can be combined with other embodiments disclosed herein, the present disclosure describes a method for storing bit values of at least one output terminal of a set-reset latch circuit. The method comprises maintaining at least one signal level of the at least one output terminal using parasitic capacitance.

According to a further aspect which can be combined with other embodiments disclosed herein, the at least one signal level is maintained during a reset phase.

According to a further aspect which can be combined with other embodiments disclosed herein, the method further comprises receiving a first input signal Mid+ and a second input signal Mid− at the set-reset latch circuit, providing a first output signal level to the at least one output terminal when the first input signal Mid+ is at a first input signal level and the second input signal Mid− is at a second input signal level, and providing a second output signal level to the at least one output terminal when the first input signal Mid+ is at the second input signal level and the second input signal Mid− is at the first input signal level. During the reset phase, the first input signal Mid+ is at the second input signal level and the second input signal Mid− is at the second input signal level.

According to a further aspect which can be combined with other embodiments disclosed herein, the at least one output terminal comprises a first output terminal providing a first output signal Out+, and a second output terminal providing a second output signal Out− having an output signal level that is the inverse of the output signal level of the first output signal.

According to a further aspect which can be combined with other embodiments disclosed herein, the dynamic latch is further configured to receive a clock signal comprising a plurality of clock edges, and the first input signal Mid+ and second input signal Mid− are generated in response to receiving a clock edge of the plurality of clock edges.

According to some aspects, the present disclosure describes a logic circuit, comprising the dynamic comparator circuit described above, and one or more additional circuit components. The at least one output terminal is configured to provide at least one respective output signal to the one or more additional circuit components, and the parasitic capacitance is a parasitic capacitance of the one or more additional circuit components.

According to a further aspect which can be combined with other embodiments disclosed herein, the method further comprises receiving, at a dynamic latch, a clock signal comprising a plurality of clock edges, and generating, at the dynamic latch, the first input signal Mid+ and second input signal Mid− in response to receiving a clock edge of the plurality of clock edges.

According to a further aspect which can be combined with other embodiments disclosed herein, the at least one output terminal is configured to provide at least one respective output signal to one or more additional circuit components of a logic circuit, and the parasitic capacitance is a parasitic capacitance of the one or more additional circuit components.

According to a further aspect which can be combined with other embodiments disclosed herein, the one or more additional circuit components includes one or more registers.

### BRIEF DESCRIPTION OF THE DRAWINGS

Reference will now be made, by way of example, to the accompanying drawings which show example embodiments of the present application, and in which:

FIG. 1 (prior art) is a circuit diagram showing an example conventional SR latch suitable for use in a dynamic comparator.

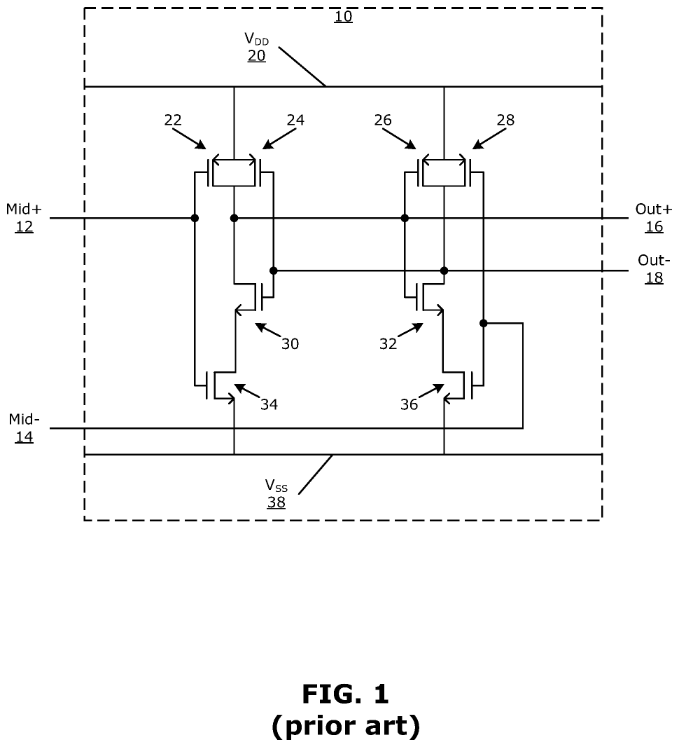

FIG. 2 is a block diagram showing an example logic circuit using a dynamic comparator according to examples described herein.

FIG. 3 is a block diagram showing an example dynamic comparator of the logic circuit of FIG. 2.

FIG. 4 is a circuit diagram showing an example set-reset latch of the dynamic comparator of FIG. 3.

FIG. 5 is a timing diagram of six signals of the dynamic comparator of FIG. 3 along a shared time axis.

FIG. 6 is a flowchart showing steps of an example method for storing bit values in an SR latch using parasitic capacitance, according to example embodiments described herein.

Similar reference numerals may have been used in different figures to denote similar components.

### DESCRIPTION OF EXAMPLE EMBODIMENTS

The present disclosure describes example circuits and methods for storing bit values in capacitors of a set-reset latch of a dynamic comparator. In some embodiments, a capacitor-based SR latch makes use of the parasitic capacitances present at its output to store a digital bit value.

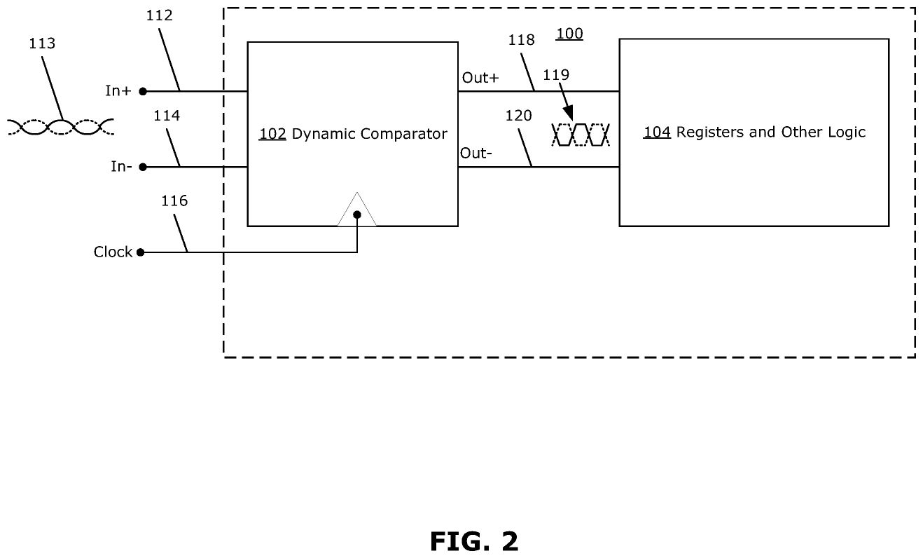

FIG. 2 shows an example logic circuit 100 using a dynamic comparator 102. The logic circuit 100 can be any circuit making use of a dynamic comparator 102, such as a digital receiver device employing the dynamic comparator 102 as an ADC to convert analog signals received over a transmission medium into digital data.

The dynamic comparator 102 samples a differential analog signal 113 at its inputs, In+ 112 and In− 114, based on a received clock signal 116. The dynamic comparator 102 generates a differential digital signal 119 at its outputs Out+ 118 and Out− 120, which is used to drive registers and other logic 104 of the logic circuit 100.

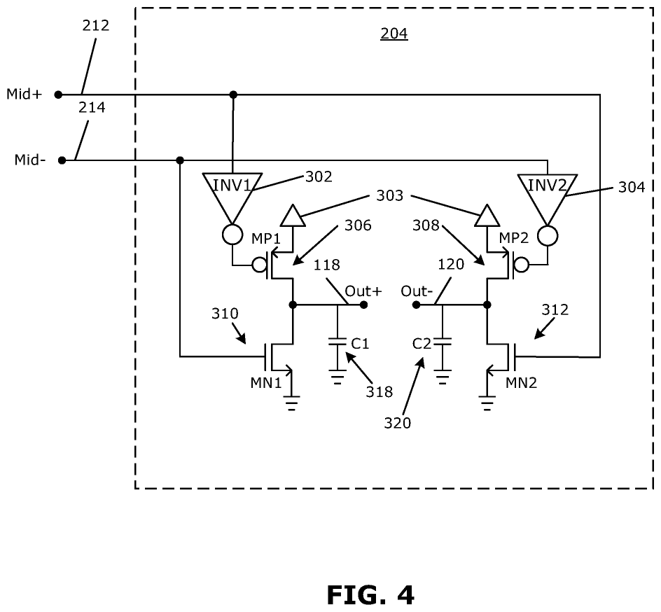

The dynamic comparator 102 also drives parasitic capacitances associated with the wiring and circuitry of the logic circuit 100. In this example, the parasitic capacitance associated with the wiring and circuitry of the registers and other logic 104 at the outputs 118, 120 of the dynamic comparator 102 will be illustrated and described as part of a set-reset latch of the dynamic comparator 102 itself in reference to FIG. 4 below, but it will be appreciated that these parasitic capacitances are not a function solely of the design or operation of the dynamic comparator 102 or its SR latch but also of the integration of those components into the logic circuit 100 as a whole.

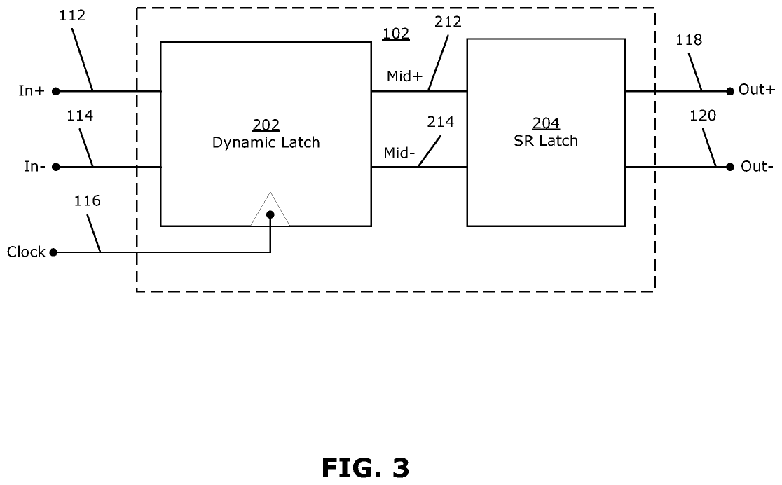

FIG. 3 shows an example implementation of the dynamic comparator 102 of the logic circuit 100 of FIG. 2. The dynamic comparator 102 includes a dynamic latch 202 and a set-reset (SR) latch 204. The dynamic latch 202 may be a conventional dynamic latch, e.g., a StrongARM latch or a double-tail latch. The dynamic latch samples the analog signal at the inputs 112, 114 based on the clock signal 116, and it generates a differential digital signal at its outputs Mid+ 212 and Mid− 214. The outputs of the dynamic latch 202, Mid+ 212 and Mid− 214, are provided to the SR latch 204, which uses the signal values at those outputs 212, 214 to generate the outputs 118, 120 of the dynamic comparator 102, as described in greater detail below with reference to FIG. 4.

FIG. 4 is a circuit diagram showing an example set-reset latch 204 of the dynamic comparator 102 of FIG. 3. The outputs of the dynamic latch 202, Mid+ 212 and Mid− 214, are provided to a first inverter INV1 302 and a second inverter INV2 304, respectively, each of which inverts the value of its respective signal and provides the inverted signal value to the gate terminal of a first transistor MP1 306 and a second transistor MP2 308, respectively. The first transistor MP1 306 and second transistor MP2 308 are PMOS transistors. The source terminal of each of the first transistor MP1 306 and second transistor MP2 308 are connected to a power source 303 (e.g., voltage source V_{DD}), and the drain terminal of each is connected to a respective output Out+ 118, Out− 120.

The outputs of the dynamic latch 202, Mid+ 212 and Mid− 214, are also provided to the gate terminals of a third transistor MN1 310 and a fourth transistor MN2 312, respectively. The third transistor MN1 310 and fourth transistor MN2 312 are NMOS transistors. Each of the third transistor MN1 310 and fourth transistor MN2 312 have their drain terminals connected to a respective output Out+ 118, Out− 120, and their source terminals connected to ground.

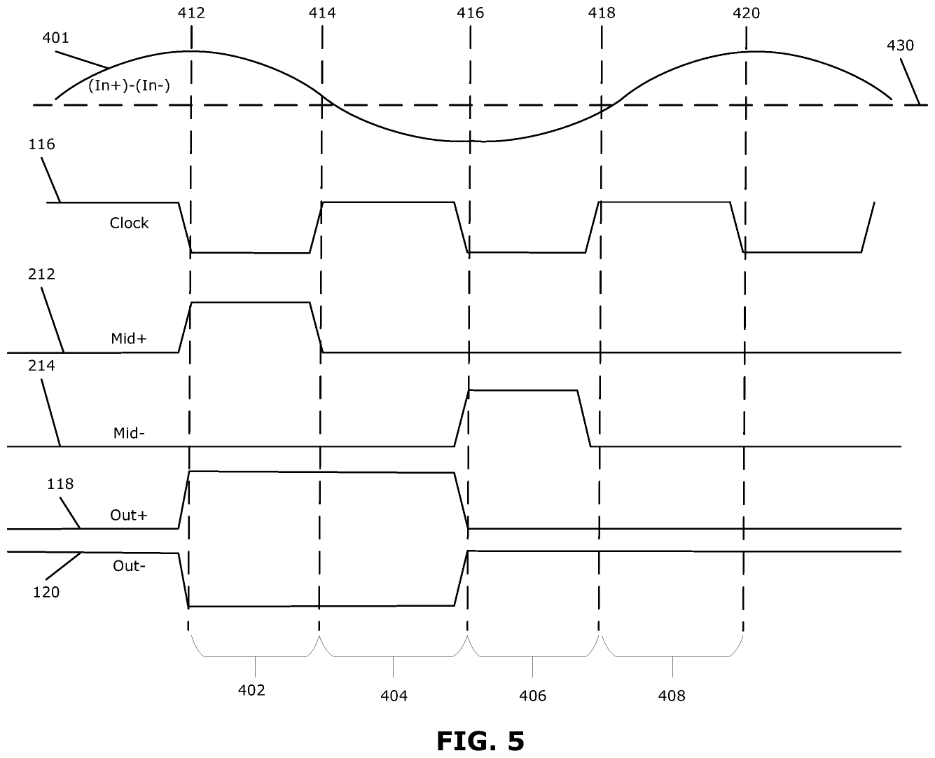

The first output Out+ 118 is connected to ground by a first parasitic capacitance 318, and the second output Out− 120 is connected to ground by a second parasitic capacitance 320, representing the parasitic capacitance associated with the entire logic circuit 100 in which the SR latch 204 operates, as described above. These parasitic capacitances 318, 320 are used by the SR latch 204 to store bit values during the reset phase, as described in detail below with reference to FIG. 5. It will be appreciated that other variants of SR latch architecture may be used in place of the example SR latch 204 architecture of FIG. 4, as long as the parasitic capacitance of the circuit is used to store bit values. In addition, individual components of the SR latch 204 may be replaced with functional equivalents, such as other transistor types being used in place of the MOSFET transistors 306, 308, 310, 312 shown in FIG. 4, or other signal value inversion techniques being used in place of the inverters 302, 304.

FIG. 5 is a timing diagram showing levels (e.g., voltage levels) of six signals of the dynamic comparator of FIG. 3 along a shared horizontal time axis extending from left to right, illustrating an example of operation of the SR latch 204 of FIG. 4. The differential analog signal level 401 is shown at the top as an analog differential signal calculated as the level of In+ 112 minus the level of In− 114, i.e. (In+)−(In−). The level of the differential analog signal level 401 is shown with respect to a zero value 430 representing (In+=In−).

The clock signal 116 is shown below the differential analog signal level 401. Below that, the first dynamic latch output Mid+ 212 is shown, then the second dynamic latch output Mid− 214. Below that, the first dynamic comparator output Out+ 118 is shown, then the second dynamic comparator output Out− 120.

In this example, the dynamic comparator 102 samples on the falling edge of the clock signal 116, and the Mid+ 212 and Mid− 214 signals are driven low when the dynamic latch 202 is in the reset phase. In some examples, the dynamic comparator 102 may sample at another point of the clock signal 116 (e.g., rising edge, or both rising and falling edges). In some examples, Mid+ 212 and Mid− 214 may be driven high in reset: in such embodiments, the SR latch 204 could be modified such that first inverter INV1 302 and second inverter INV2 304 drive the gates (i.e. base terminals) of third transistor MN1 310 and fourth transistor MN2 312 instead of first transistor MP1 306 and second transistor MP2 308.

Four phases are shown in the timing diagram of FIG. 5: Sample Phase 1 402, in which MP1 and MN2 are on, and MP2 and MN1 are off; Reset Phase 1 404, in which MP1, MN2, MP2 and MN1 are all off, and the output values Out+ 118 and Out− 120 are held by the respective parasitic capacitances 318, 320; Sample Phase 2 406, in which MP2 and MN1 are on, and MP1 and MN2 are off; and Reset Phase 2 408, in which MP1, MN2, MP2 and MN1 are all off, and the output values Out+ 118 and Out− 120 are held by the respective parasitic capacitances 318, 320.

Near the beginning of Sample Phase 1 402, at first time 412, the falling edge of the clock signal 116 triggers the dynamic latch 202 to sample a positive value of the differential analog signal level 401 based on the inputs In+ 112 and In− 114. Based on this positive value of the sample of the differential analog signal level 401, the dynamic latch 202 generates a high voltage level for Mid+ 212, which rises at first time 412 to a high voltage and thereby turns on first transistor MP1 306 and fourth transistor MN2 312, which, in turn, drive the voltage level of Out+ 118 high and the voltage level of Out− 120 low during Sample Phase 1 402.

Reset Phase 1 404 is triggered at second time 414 by the rising edge of the clock signal 116. Both Mid+ 212 and Mid− 214 are driven to a low voltage value. The four transistors in the SR latch 204 (MP1 306, MN1 310, MP2 308, and MN2 312) are turned off, and the voltage levels of Out+ 118 and Out− 120 are held by the first parasitic capacitance 318 and second parasitic capacitance 320 respectively.

At the beginning of Sample Phase 2 406, at third time 416, the differential analog signal level 401 is negative. Thus, Mid− 214 rises to a high voltage level during Sample Phase 2 406, thereby turning on second transistor MP2 308 and third transistor MN1 310. The outputs Out+ 118 and Out− 120 are inverted.

At fourth time 418, at the beginning of Reset Phase 2 408, transistors MP1 306, MN1 310, MP2 308, and MN2 312 are turned off again, and the inverted output voltages of Out+ 118 and Out− 120 are held by the parasitic capacitances 318, 320 respectively until the end of Reset Phase 2 408 at fifth time 420.

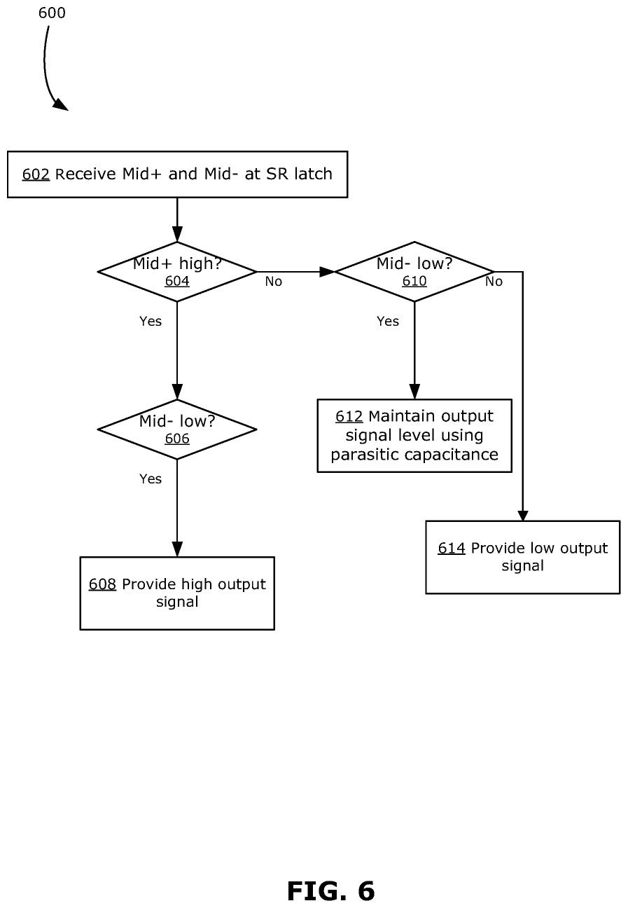

FIG. 6 shows an example method 600 for maintaining a bit value at an output terminal of a SR latch using parasitic capacitance. At 602, a set-reset latch circuit (e.g. SR latch 204) receives a first input signal Mid+ 212 and a second input signal Mid− 214. At 604, the signal level of the first input signal Mid+ 212 checked. If the first input signal level (Mid+ 212) is at a first input signal level (shown as a “high” level, e.g., a voltage level sufficient to activate transistors MP1 306 and MN2 312), the method 600 proceeds to step 604, otherwise it proceeds to step 610.

At 606, the signal level of the second input signal Mid− 214 checked. If the second input signal level (Mid− 214) is at a second input signal level (shown as a “low” level, e.g., a voltage level insufficient to activate transistors MP2 308 and MN1 310), the method 600 proceeds to step 608. (Note that it should be invalid for both Mid+ 212 and Mid− 214 to provide high signal values simultaneously if the SR latch is implemented as in FIG. 4.)

At 608, the SR latch 204 provides a first output signal level (shown as a high output signal corresponding to a “1” bit) to at least one output terminal (e.g., differentially to output terminals Out+ 118 and Out− 120).

At 610, the signal level of the second input signal Mid− 214 checked. If the second input signal level (Mid− 214) is at a second input signal level (shown as a “low” level, e.g., a voltage level insufficient to activate transistors MP2 308 and MN1 310), the method 600 proceeds to step 612, otherwise it proceeds to step 614.

At 612, in response to determining that the first input signal level (Mid+ 212) and second input signal level (Mid 214) are both at a second input signal level (“low”), indicating a reset phase, the SR latch 204 maintains at least one signal level of the at least one output terminal (e.g., output signal levels of Out+ 118 and Out− 120) using parasitic capacitance, as described above.

At 614, in response to determining that the first input signal level (Mid+ 212) is at a second input signal level (“low”), and the second input signal level (Mid 214) is at a first input signal level (“high”), the SR latch 204 provides a second output signal level (shown as a low output signal corresponding to a “0” bit) to at least one output terminal (e.g., differentially to output terminals Out+ 118 and Out− 120).

It will be appreciated that the output terminals indicated in method 600 may in some examples be a first output terminal providing a first output signal Out+, and a second output terminal providing a second output signal Out− having an output signal level that is the inverse of the output signal level of the first output signal.

Although the present disclosure describes methods and processes with steps in a certain order, one or more steps of the methods and processes may be omitted or altered as appropriate. One or more steps may take place in an order other than that in which they are described, as appropriate.

Although the present disclosure is described, at least in part, in terms of methods, a person of ordinary skill in the art will understand that the present disclosure is also directed to the various components for performing at least some of the aspects and features of the described methods, be it by way of hardware components, software or any combination of the two. Accordingly, the technical solution of the present disclosure may be embodied in the form of a software product. A suitable software product may be stored in a pre-recorded storage device or other similar non-volatile or non-transitory computer readable medium, including DVDs, CD-ROMs, USB flash disk, a removable hard disk, or other storage media, for example. The software product includes instructions tangibly stored thereon that enable a processing device (e.g., an embedded processor, a personal computer, a server, or a network device) to execute examples of the methods disclosed herein.

The present disclosure may be embodied in other specific forms without departing from the subject matter of the claims. The described example embodiments are to be considered in all respects as being only illustrative and not restrictive. Selected features from one or more of the above-described embodiments may be combined to create alternative embodiments not explicitly described, features suitable for such combinations being understood within the scope of this disclosure.

Also, although the systems, devices and processes disclosed and shown herein may comprise a specific number of elements/components, the systems, devices and assemblies could be modified to include additional or fewer of such elements/components. For example, although any of the elements/components disclosed may be referenced as being singular, the embodiments disclosed herein could be modified to include a plurality of such elements/components. The subject matter described herein intends to cover and embrace all suitable changes in technology.

1. A set-reset latch circuit, comprising:
at least one output terminal;
a plurality of transistors collectively configured to:
receive a first input signal Mid+ and a second input signal Mid−;
provide a first output signal level to the at least one output terminal when the first input signal Mid+ is at a first input signal level and the second input signal Mid− is at a second input signal level; and
provide a second output signal level to the at least one output terminal when the first input signal Mid+ is at the second input signal level and the second input signal Mid− is at the first input signal level,
wherein the at least one output terminal maintains its signal level using parasitic capacitance when the first input signal Mid+ is at the second input signal level and the second input signal Mid− is at the second input signal level.

2. The set-reset latch circuit of claim 1, wherein the at least one output terminal comprises:
a first output terminal providing a first output signal Out+; and
a second output terminal providing a second output signal Out− having an output signal level that is the inverse of the output signal level of the first output signal.

3. The set-reset latch circuit of claim 2, wherein the plurality of transistors comprises:
a first transistor gated by an inverted version of the first input signal Mid+ and providing its output to the first output terminal;
a second transistor gated by an inverted version of the second input signal Mid− and providing its output to the second output terminal;
a third transistor gated by the second input signal Mid− and receiving the first output signal at its drain terminal; and
a fourth transistor gated by the first input signal Mid+ and receiving the second output signal at its drain terminal.

4. A dynamic comparator circuit, comprising:
the set-reset latch circuit of claim 1; and
a dynamic latch configured to:
receive two comparator input signals;
generate the first input signal Mid+ and second input signal Mid− in response thereto; and
provide the first input signal Mid+ and second input signal Mid− to the set-reset circuit.

5. The dynamic comparator circuit of claim 4, wherein:
the dynamic latch is further configured to receive a clock signal comprising a plurality of clock edges; and
the first input signal Mid+ and second input signal Mid− are generated in response to receiving a clock edge of the plurality of clock edges.

6. A logic circuit, comprising:
the dynamic comparator circuit of claim 4; and
one or more additional circuit components,
wherein:
the at least one output terminal is configured to provide at least one respective output signal to the one or more additional circuit components; and
the parasitic capacitance is a parasitic capacitance of the one or more additional circuit components.

7. The logic circuit of claim 6, wherein the one or more additional circuit components includes one or more registers.

8. A method for storing bit values of at least one output terminal of a set-reset latch circuit, comprising:
maintaining at least one signal level of the at least one output terminal using parasitic capacitance.

9. The method of claim 8, wherein the at least one signal level is maintained during a reset phase.

10. The method of claim 9, further comprising:
receiving a first input signal Mid+ and a second input signal Mid− at the set-reset latch circuit;
providing a first output signal level to the at least one output terminal when the first input signal Mid+ is at a first input signal level and the second input signal Mid− is at a second input signal level; and
providing a second output signal level to the at least one output terminal when the first input signal Mid+ is at the second input signal level and the second input signal Mid− is at the first input signal level,
wherein, during the reset phase, the first input signal Mid+ is at the second input signal level and the second input signal Mid− is at the second input signal level.

11. The method of claim 8, wherein the at least one output terminal comprises:
a first output terminal providing a first output signal Out+; and
a second output terminal providing a second output signal Out− having an output signal level that is the inverse of the output signal level of the first output signal.

12. The method of claim 8:
further comprising:
receiving, at a dynamic latch, a clock signal comprising a plurality of clock edges; and
generating, at the dynamic latch, the first input signal Mid+ and second input signal Mid− in response to receiving a clock edge of the plurality of clock edges.

13. The method of claim 8, wherein:
the at least one output terminal is configured to provide at least one respective output signal to one or more additional circuit components of a logic circuit; and
the parasitic capacitance is a parasitic capacitance of the one or more additional circuit components.

14. The method of claim 13, wherein the one or more additional circuit components includes one or more registers.
